(19) United States
(12) Patent Application Publication
(10) Pub. No.: US 2012/0306021 A1
(43) Pub. Date: Dec. 6, 2012

(54) SEMICONDUCTOR DEVICE AND METHOD OF FABRICATION

(75) Inventors: Srikanth SAMAVEDAM, Fishkill, NY (US); Bipul PAUL, Fishkill, NY (US); Srinath KRISHNAN, Campbell, CA (US); Sriram BALASUBRAMANIAN, Fremont, CA (US)

(73) Assignee: GLOBALFOUNDRIES INC., Grand Cayman (KY)

(21) Appl. No.: 13/153,179

(22) Filed: Jun. 3, 2011

(51) Int. Cl. H01L 27/092; H01L 21/8238

(52) U.S. Cl. 257/369; 438/199; 257/E27.062; 257/E21.632

(57) ABSTRACT

A semiconductor device is provided that includes a first pair of P channel field effect transistors (PFET) with a common source connected to a voltage contact and a gate connected to a drain of the other PFET and a pair of N channel field effect transistors (NFET) sized smaller than the first pair of PFETs with a drain connected to the drain of the respective PFET of the first pair of PFETs, a common source connected to a ground contact, and a gate connected to the drain of an opposite PFET of the first pair of PFETs. Additionally, a second pair of PFETs sized larger than the NFETs and approximately one-half that of the first pair of PFETS, each of the second pair of PFETs having a drain respectively coupled to a connection linking the respective drain of the NFET of the pair of NFETs to the drain of the PFET of the first pair of PFETs. Complementary bit lines are included, each of the complementary bit lines respectively connected to a source of the second pair of PFETs. Finally, a word line connected to a gate of each of the second pair of PFETs. A method for forming the semiconductor device is also disclosed.

### TECHNICAL FIELD

The technical field relates to semiconductor devices and to methods for their fabrication, and more particularly, relates to static random access memory (SRAM) devices having P channel field-effect transistors (PFETs) as the passgate devices and to methods for their fabrication.

### BACKGROUND

The majority of present day integrated circuits (ICs) are implemented by using a plurality of interconnected field effect transistors (FETs). A FET includes a gate electrode as a control electrode and spaced apart source and drain regions formed in a semiconductor substrate and between which a current can flow. A control voltage applied to the gate electrode controls the flow of current through a channel between the source and drain regions. Depending upon doping during the fabrication processes a FET can be an n-channel device (NFET) or a p-channel device (PFET).

One of the most important semiconductor devices is the static random access memory (SRAM) cell used in many demanding memory applications. Conventionally, a six-transistor (6T) SRAM cell includes two PFETs for a pull-up operation, two NFETs for pull down, and two NFETs for input/output (i.e., passgate or transfer) access. A conventional 6T SRAM cell 100 is shown in FIGS. 1. P1 (102) and N1 (104) form an inverter which is cross-coupled with another inverter formed by P2 (106) and N2 (108). N3 (110) and N4 (112) are the NFET passgate access devices that control reading from and writing into the SRAM cell 100. To form an SRAM array, multiple (often hundreds of millions) SRAM cells 100 are arranged in rows and columns with the cells of the same row sharing one word line (WL) 114, while cells of the same column share the same bit line (BL) pair of BLT (116) and BLC (the logical compliments of BLT) 118.

During standby, the WL 114 is at logic low (i.e., VSS or ground 120) and the bit lines (116 and 118) are biased to the VDD voltage level 121. Thus, the NFET passgate devices N3 (110) and N4 (112) are shut off. A logical 1 is maintained in the SRAM cell 100 with P1 (102) and N2 (108) ON (i.e., conducting) and P2 (106) and N1 (104) are OFF. This causes cell node 122 to be at logic high (i.e., VDD) while cell node 124 is at logic low (i.e., ground). Conversely, a logical 0 is maintained in the SRAM cell 100 when P2 (106) and N1 (104) are ON, and P1 (102) and N2 (108) are OFF, which forces the cell node 124 to logic high and the cell node 122 to logic low.

During a read operation, either BLT (116) or BLC (118) is pulled down from its standby logic high level upon activation of the word line 114 which causes the NFET passgates to conduct. BLT is pulled down if the cell is at logical 0, whereas BLC is pulled down if the cell is at logical 1. Sense amplifiers detect this and generate the digital signals for external circuitry requesting the memory read operation. Also, either a logic 1 or logic 0 can be stored in the SRAM cell 100 during a write operation. To write a logic 1, BLT 116 is driven to high and BLC 118 to low, which shuts OFF N1 (104) and P2 (106), while turning on N2 (108) and P1 (102). Conversely, to write a 0, BLT 116 is forced to low and BLC 118 to high.

SRAM cell 100 is designed to meet a minimum level of read stability for a given memory size and process. Read stability can be loosely defined as the probability that the SRAM cell 100 will flip its stored binary value during a read operation. SRAM cell 100 is more susceptible to noise during a read operation because the voltage at the low node, (for example node 124), will rise due to the voltage division by NFETs 108 and 112 between precharged bit line 118 and the ground node 120 when NFET 118 is activated by a high signal on word line 114. Mismatch in threshold voltage of neighboring transistors, such as NFETs 108 and 112, for example, reduces the available static noise margin of SRAM cell 100 and therefore reduces read stability. Accordingly, it is common to increase the ratio of the transconductance of NFET 108 relative to that of NFET 112 by sizing NFET 108 to be larger than NFET 112.

However, NFETs are known to have a greater variability than PFETs. Historically, NFET variability has been tolerable in larger geometries (e.g., about 65 nm), however, at geometries below 22 nm, the variability effect becomes more pronounced and a detriment to SRAM cell operation. Accordingly, a need exists to provide methods for fabricating an integrated circuit forming an SRAM cell that reduces the variability effects of NFETs. Additionally it is desirable to provide SRAM cells capable of reducing NFET variability while maintaining SRAM performance and facilitating high density for forming SRAM integrated circuits in small geometry implementations. Furthermore, other desirable features and characteristics of the present invention will become apparent from the subsequent detailed description and the appended claims, taken in conjunction with the accompanying drawings and the foregoing technical field and background.

### BRIEF SUMMARY

In accordance with one embodiment a method for fabricating a semiconductor device is provided that forms a static random access memory cell by forming a first pair of P channel field effect transistors (PFET) with a common source connected to a voltage contact and a gate connected to a drain of the other PFET. Then, a pair of N channel field effect transistors (NFET) is formed that are sized smaller than the first pair of PFETs each having a drain connected to the drain of a respective PFET of the first pair of PFETs, a common source connected to a ground contact, and a gate connected to the drain of an opposite PFET of the first pair of PFETs. Next, a second pair of PFETs sized larger than the NFETs and approximately one-half that of the first pair of PFETS is formed, each of the second pair of PFETs having a drain respectively coupled to a connection linking the respective drain of the NFET of the pair of NFETs to the drain of the PFET of the first pair of PFETs. Also, complementary bit lines are formed, each of the complementary bit lines respectively connected to a source of the second pair of PFETs and a word line is formed that is connected to a gate of each of the second pair of PFETs.

In accordance with a further embodiment, a method for fabricating a semiconductor device is provided that forms a static random access memory cell including first and second inverters each coupled to a voltage contact and a ground contact. The first inverter is formed of a first p-channel field effect transistor (PFET) having a drain coupled to a drain of a first n-channel field effect transistor (NFET) to form a first cell node, the first NFET having a smaller size than the first PFET and the first PFET and first NFET having a common gate coupled to a second cell node of the second inverter. The second inverter is formed of a second PFET sized approximately the same as the first PFET and having a drain coupled to a drain of a second NFET to form the second cell node, the first NFET having approximately the same size than the first NFET and the second PFET and second NFET having a common gate coupled to a first cell node of the first inverter. Also, a pair of PFET passgates is formed each sized larger than the NFETs of the first and second inverters and approximately one-half that of the PFETs of the first and second inverters, each of the PFET passgates having a drain respectively coupled the first and second cell nodes. Also, complementary bit lines are formed, each of the complementary bit lines respectively connected to a source of the pair of PFET passgates, and a word line is formed to be connected to a gate of each of the pair of PFET passgates.

In accordance with yet another embodiment a semiconductor device is provided that includes a first pair of P channel field effect transistors (PFETs) with a common source connected to a voltage contact and a gate connected to a drain of the other PFET and a pair of N channel field effect transistors (NFETs) sized smaller than the first pair of PFETs with a drain connected to the drain of the respective PFET of the first pair of PFETs, a common source connected to a ground contact, and a gate connected to the drain of an opposite PFET of the first pair of PFETs. Additionally, a second pair of PFETs sized larger than the NFETs and approximately one-half that of the first pair of PFETS, each of the second pair of PFETs having a drain respectively coupled to a connection linking the respective drain of the NFET of the pair of NFETs to the drain of the PFET of the first pair of PFETs. Complementary bit lines are included, each of the complementary bit lines respectively connected to a source of one of the second pair of PFETs. Finally, a word line is connected to a gate of each of the second pair of PFETs.

### BRIEF DESCRIPTION OF THE DRAWINGS

The present disclosure will hereinafter be described in conjunction with the following drawing figures, wherein like numerals denote like elements, and wherein

FIG. 1 is a schematic diagram of a conventional 6T SRAM cell; and

FIG. 2 is a schematic diagram of a 6T SRAM cell according to exemplary embodiments of the present disclosure;

FIG. 3 is an illustration of the 6T SRAM cell of FIG. 2 arranged into an SRAM array according to exemplary embodiments of the present disclosure; and.

FIG. 4 is a schematic diagram of an alternate embodiment for an 8T dual-port SRAM according to the present disclosure.

### DETAILED DESCRIPTION

The following detailed description is merely exemplary in nature and is not intended to limit the disclosure or the application and uses of the disclosure. Furthermore, there is no intention to be bound by any expressed or implied theory presented in the preceding technical field, background, brief summary or the following detailed description.

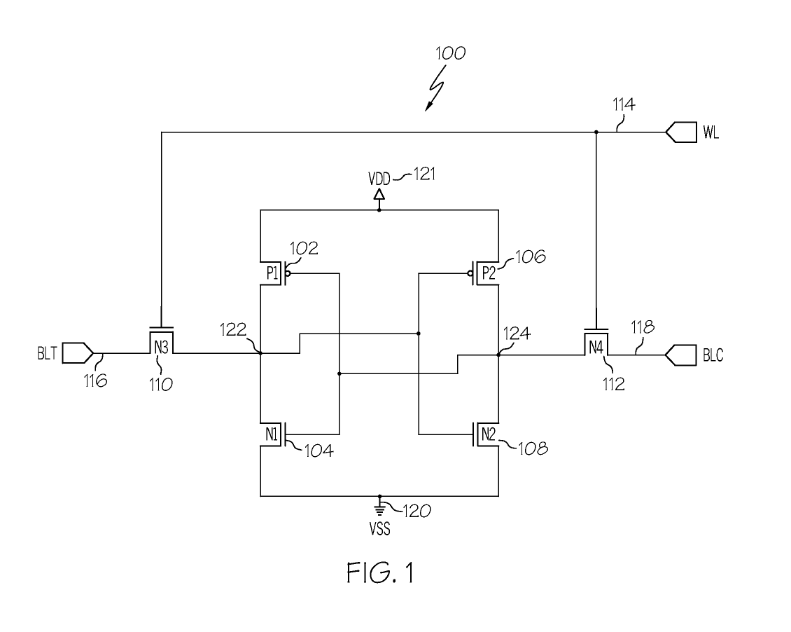

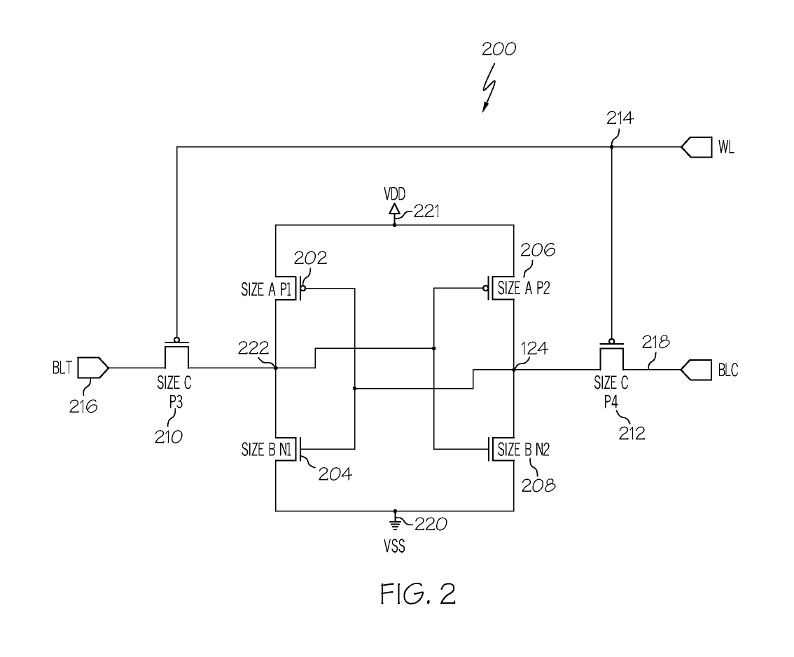

Referring now to FIG. 2, a six-transistor (6T) SRAM cell 200 according to various embodiment of the present disclosure includes two PFETs for a pull-up operation, two NFETs for pull down, and two PFETs for input/output (i.e., passgate or transfer) access. The pair of pull-up PFETs has a common source contact to VDD and a gate contact coupled to the drain of the other pull-up PFET. Comparatively, each of the pair of PFETs (202 and 206) is larger in size than the pull-up PFETs 102 and 106 of FIG. 1. The pair of NFETs (204 and 208) has a common source at ground (VSS) and drain connected to the drains of the pair of PFETs (202 and 206). While the conventional SRAM cell 100 employs NFETs for the passgates (110 and 112 of FIG. 1), PFET passgates (210 and 212) have been shown to have better stability and lower power loss than NFETs, which (as noted above) typically have a higher variability leading to standby current loss. Thus, a second pair of PFETs (210 and 212) replaces two NFETs (110 and 112 of FIG. 1) as passgates for the SRAM cell 200 offering an advantage of lowering the overall Vmin of the SRAM cell. Additionally, as noted above, the inverter NFETs 204 and 208 are greatly reduced in size and act as load elements of the SRAM cell 200 offering further immunity to NFET variability.

Accordingly, in accordance with embodiments of the present disclosure, P1 (202) and N1 (204) form a first inverter which is cross-coupled with a second inverter formed by P2 (206) and N2 (208). Unlike the conventional SRAM cell 100, the SRAM cell 200 uses the enlarged (denoted “Size A) PFETs (202 and 206) as the gain transistors, while the NFETs (204 and 208) take on the role of load elements for the SRAM cell 200. Consequently, the size (denoted “Size B) of NFETs (204 and 208) can be reduced compared to the “Size A” PFETs (202 and 206) as well as being greatly reduced from the size of the NFETs (104 and 108) of the SRAM cell 100 (FIG. 1). Also, as noted above, the inverter PFETs (202 and 206) may be enlarged over those of the SRAM cell 100 of FIG. 1 and be sized according to contemporary design guidelines to be about 1.5 times the width of the NFETs (204 and 208) of the SRAM cell 200. The SRAM cell 200 further reduces NFET variability by using PFETs P3 (210) and P4 (212) as the passgate devices, which control reading from and writing into the SRAM cell 200. The size (denoted “Size C”) of the passgate PFETs (210 and 210) follow conventional design parameters being about one-half that of the latch or inverter PFETs (202 and 206), but larger than the NFETs NFETs (204 and 208).

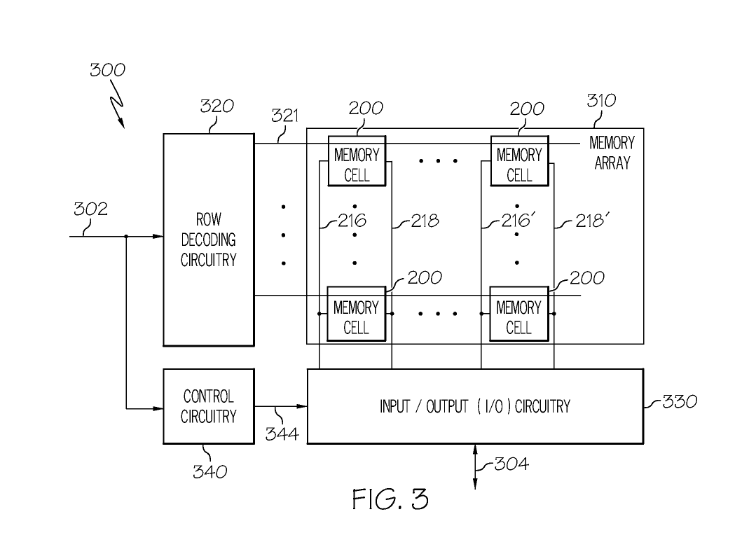

To fabricate (form) the SRAM cell 200, conventional semiconductor processes can be employed, preferably in the sub 22 nm geometries, using the FET size parameters noted above. Also, as discuss in more detail in conjunction with FIG. 3 (below), to form an SRAM array, multiple (often hundreds of millions) SRAM cells 200 are arranged in rows and columns with the cells of the same row sharing one word line (WL) 214, while cells of the same column share the same bit line (BL) pair of BLT (216) and BLC (the logical compliments of BLT) 218.

During standby, the WL 214 is biased to a logic high voltage level and bit lines (216 and 218) are discharged to logic low (i.e., ground 220). Thus, the NFET passgate devices P3 (210) and P4 (212) are shut off. A logical 1 is maintained in the SRAM cell 200 with P1 (202) and N2 (208) ON (i.e., conducting) and P2 (206) and N1 (204) OFF. This causes the cell node 222 to be at logic high (i.e., VDD) while cell node 224 is at logic low (i.e., VSS or ground 220). Conversely, a logical 0 is maintained in the SRAM cell 200 when P2 (206) and N1 (204) are ON, and P1 (202) and N2 (208) are OFF, which forces the cell node 224 to logic high and the cell node 222 to logic low.

Operationally (either post fabrication testing or in a specific implementation), during a read operation, both BLT (216) and BLC (218) are (pre-discharged) in their standby state to a logic low level (220). Upon energizing (activating) the word line to logic low, the cell node (222 or 224) that is at a logic 1 level will tend to pull up toward VDD (221), which can be detected (either directly or by a split (differential) between the bit line voltages) by sense amplifiers to generate the digital signals for external circuitry requesting the memory read operation. Also, either a logic 1 or logic 0 can be stored in the SRAM cell 200 during a write operation. To write a logic 1, BLT 216 is driven to high and BLC 218 to low, which shuts OFF N1 (204) and P2 (206), while turning on N2 (208) and P1 (202). Conversely, to write a 0, BLT 216 is forced to low and BLC 218 to high.

Referring now to FIG. 3, the SRAM cell 200 (FIG. 2) is illustrated formed into a memory device 300. In one embodiment, the memory device 300 includes a memory array 310, row decoding circuitry 320, input/output (I/O) circuitry 330, and control circuitry 340. The memory array 310 includes multiple rows and multiple columns of memory cells, any suitable one or more of which may be a memory cell having a p-channel passgate, such as SRAM cell 200 (FIG. 2). As illustrated, the row decoding circuitry 320 is coupled to receive at least a portion of an address on address lines 302 and to generate a signal on a word line, such as a word line 321 for example, to select memory cells in a row of memory array 310 in response to the received address portion. For comparison to FIG. 2, the word line 321 corresponds to WL 214 of FIG. 2. Row decoding circuitry 320 generates a low voltage signal on a word line to activate PFET passgates (such as PFETs 210 and 212 of FIG. 2) of memory cells 200 in a row of memory array 310. A single pair of complementary bit lines (216 and 218) is common to multiple memory cells in one column of memory array 310 as shown. The I/O circuitry 330 generally includes one or more sense amplifiers. A sense amplifier senses the complementary signals on a select bit line pair of multiple bit line pairs (216/218 and 216′/218′) corresponding to multiple columns of memory array 310 and outputs on one or more data lines 304 corresponding amplified complementary signals or an amplified signal representative of a binary value corresponding to the sensed complementary signals. The I/O circuitry 330 also includes one or more write drivers that receive a signal or complementary signals representative of a binary value on one or more data lines 304 to assert corresponding complementary signals on a select bit line pair (216/218 and 216′/218′) of multiple bit line pairs corresponding to multiple columns of memory array 310. The control circuitry 340 also receives at least a portion of the address 302 and generates one or more signals on one or more column select lines 344 to select memory cells in one or more columns of memory array 310 in response to the received address portion. In this way, several (potentially hundreds of millions) SRAM cells 200 of the present disclosure can be arrayed to form an SRAM memory device 300 for use in computing or other applications.

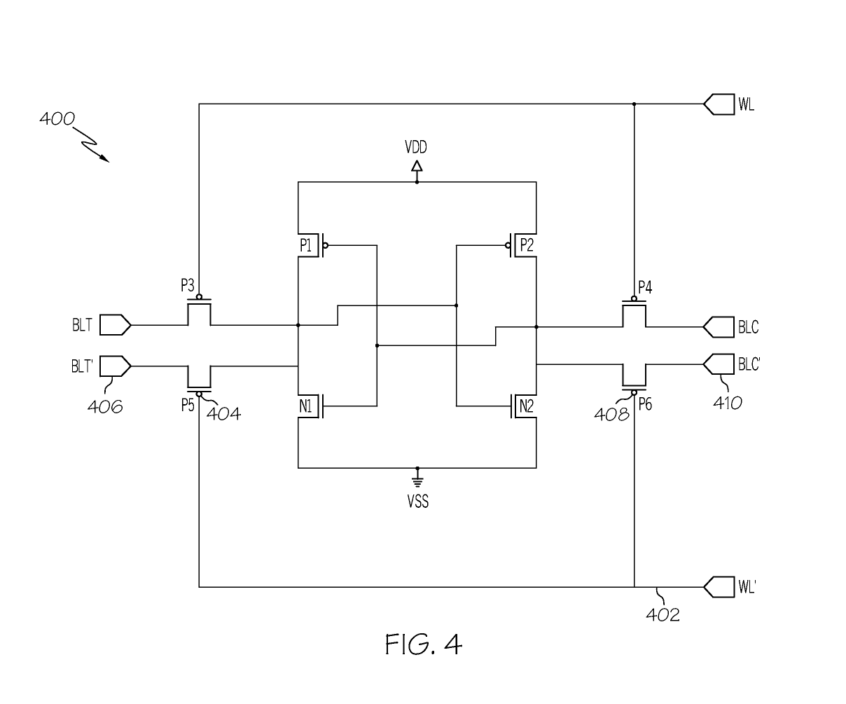

Referring now to FIG. 4, an alternate embodiment of an 8-T dual-port SRAM cell 400 is shown. As can be seen, the dual-port SRAM cell 400 is substantially the same as the SRAM cell 200, which is a single port design. Accordingly, for simplicity, common reference numerals have been omitted. The dual-port SRAM call 400 includes a second word line (WL') 402 (for the second port), which activates a second pair of PFET passgates for the second port (e.g., a third pair of PFETs for the second pair of passgates) P5 (404) and P6 (408), each coupled to a second set of complementary bit lines BLT′ (406) and BLC′ (410), respectively. Operationally, the second port functions as described above in conjunction with FIG. 2 and offers the advantage of a second port into the SRAM cell 400 that can be used for multiple read or write operations to occur simultaneously (or approximately simultaneously) as compared to one operation at a time in the 6T single port SRAM cell 200 of FIG. 2.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the disclosure in any way. Rather, the foregoing detailed description will provide those skilled in the art with a convenient road map for implementing the exemplary embodiments. It should be understood that various changes can be made in the size, spacing and doping of elements without departing from the scope of the disclosure as set forth in the appended claims and the legal equivalents thereof.

What is claimed is:

1. A method, comprising:
forming a static random access memory cell, comprising:
forming a first pair of P channel field effect transistors (PFETs) with a common source connected to a voltage contact and a gate connected to a drain of the other PFET;
forming a pair of N channel field effect transistors (NFETs) sized smaller than the first pair of PFETs with a drain connected to the drain of a respective PFET of the first pair of PFETs, a common source connected to a Vss contact, and a gate connected to the drain of an opposite PFET of the first pair of PFETs;
forming a second pair of PFETs sized larger than the NFETs and approximately one-half that of the first pair of PFETs, each of the second pair of PFETs having a drain respectively coupled to a connection linking the respective drain of the NFET of the pair of NFETs to the drain of the PFET of the first pair of PFETs;
forming complementary bit lines, each of the complementary bit lines respectively connected to a source of the second pair of PFETs; and
forming a word line connected to a gate of each of the second pair of PFETs.

2. The method of claim 1, further comprising:
connecting a voltage source to the voltage contact;
connecting the ground contact to a ground potential;
energizing the word line to a logic low level; and
energizing one of the complementary bit lines to a logic one level and the other bit line to a logic low level to store a logic one in the static random access memory cell.

3. The method of claim 1, further comprising:
connecting a voltage source to the voltage contact;
connecting the ground contact to a ground potential;
energizing the word line to a logic low level; and
energizing one of the complementary bit lines to a logic one level and the other bit line to a logic low level to store a logic zero in the static random access memory cell.

4. The method of claim 1, further comprising:
connecting a voltage source to the voltage contact;
connecting the ground contact to a ground potential;
discharging the complementary bit lines to a logic low level;
energizing the word line to the logic low level; and
detecting a voltage split in the complementary bit lines to read a logic value stored in the static random access memory cell.

5. The method of claim 1, further comprising forming a plurality of other
static random access memory cells in a row each coupled to the word line.

6. The method of claim 5, further comprising forming a plurality of rows of static random access memory cells forming a plurality of columns of cells, each row having an individual word line and each column of the static random access memory cells coupled to an individual pair of complementary bit lines.

7. The method of claim 1, further comprising:
forming a third pair of PFETs sized approximately the same as the second pair of PFETs, each of the third pair of PFETs having a drain respectively coupled to a connection linking the respective drain of the NFET of the pair of NFETs to the drain of the PFET of the first pair of PFETs;
forming second complementary bit lines, each of the second complementary bit lines respectively connected to a source of the third pair of PFETs; and
forming a second word line connected to a gate of each of the third pair of PFETs.

8. The method of claim 7, further comprising forming a plurality of other
static random access memory cells in a row, each static random access memory cells of the row having the second pair of PFETs coupled to the word line and the third pair of PFETs coupled to the second word line.

9. The method of claim 8, further comprising forming a plurality of rows of static random access memory cells forming a plurality of columns, each row having an individual word line and second word line and each column of plurality of the static random access memory cells coupled to an individual pair of complementary bit lines and second complementary bit lines.

10. A method, comprising:
forming a static random access memory cell including first and second inverters each coupled to a voltage contact and a Vss contact;
the first inverter being formed of a first p-channel field effect transistor (PFET) having a drain coupled to a drain of a first n-channel field effect transistor (NFET) to form a first cell node, the first NFET having a smaller size than the first PFET and the first PFET and first NFET having a common gate coupled to a second cell node of the second inverter;
the second inverter being formed of a second PFET sized approximately the same as the first PFET and having a drain coupled to a drain of a second NFET to form the second cell node, the second NFET having approximately the same size as the first NFET and the second PFET and second NFET having a common gate coupled to a first cell node of the first inverter;
forming a pair of PFET passgates each sized larger than the NFETs of the first and second invertors and approximately one-half that of the PFETs of the first and second inverters, each of the PFET passgates having a drain respectively coupled the first and second cell nodes;
forming complementary bit lines, each of the complementary bit lines respectively connected to a source of one of the pair of PFET passgates; and
forming a word line connected to a gate of each of the pair of PFET passgates.

11. The method of claim 10, further comprising:
connecting a voltage source to the voltage contact;
connecting the ground contact to a ground potential;
energizing the word line to a logic low level; and
energizing one of the complementary bit lines to a logic one level and the other bit line to the logic low level to store a logic one in the static random access memory cell.

12. The method of claim 10, further comprising:
connecting a voltage source to the voltage contact;
connecting the ground contact to a ground potential;
energizing the word line to a logic low level; and
energizing one of the complementary bit lines to a logic one level and the other bit line to the logic low level to store a logic zero in the static random access memory cell.

13. The method of claim 10, further comprising:
connecting a voltage source to the voltage contact;
connecting the ground contact to a ground potential;
discharging the complementary bit lines to a logic low level;
energizing the word line to the logic low level; and
detecting a voltage the one of the complementary bit lines to read a logic value stored in the static random access memory cell.

14. The method of claim 10, further comprising forming a plurality of other
static random access memory cells in a row each coupled to the word line.

15. The method of claim 14, further comprising forming a plurality of rows of static random access memory cells forming columns, each row having an individual word line and each column of the static random access memory cells coupled to an individual pair of complementary bit lines.

16. The method of claim 10, further comprising:
forming a second pair of PFET passgates sized approximately the same as the pair of PFET passgates, each of the second pair of PFET passgates having a drain respectively coupled to the first and second cell notes of the first and second inverters;
forming second complementary bit lines, each of the second complementary bit lines respectively connected to a source of the second pair of PFET passgates; and
forming a second word line connected to a gate of each of the second pair of PFET passgates.

17. The method of claim 16, further comprising forming a plurality of other
static random access memory cells in a row, each static random access memory cells of the row having the pair of PFET passgates coupled to the word line and the second pair of PFET passgates coupled to the second word line.

18. The method of claim 17, further comprising forming a plurality of rows of static random access memory cells forming columns, each row having an individual word line and second word line and each column of the static random access memory cells coupled to an individual pair of complementary bit lines and second complementary bit lines.

19. A semiconductor device, comprising:
a first pair of P channel field effect transistors (PFETs) with a common source connected to a voltage contact and a gate connected to a drain of the other PFET;
a pair of N channel field effect transistors (NFETs) sized smaller than the first pair of PFETs with a drain connected to the drain of the respective PFET of the first pair of PFETs, a common source connected to a ground contact, and a gate connected to the drain of an opposite PFET of the first pair of PFETs;
a second pair of PFETs sized larger than the NFETs and approximately one-half that of the first pair of PFETS, each of the second pair of PFETs having a drain respectively coupled to a connection linking the respective drain of the NFET of the pair of NFETs to the drain of the PFET of the first pair of PFETs;
complementary bit lines, each of the complementary bit lines respectively connected to a source of the second pair of PFETs; and
a word line connected to a gate of each of the second pair of PFETs.

20. The semiconductor device of claim 19, further comprising:
a second pair of PFET passgates sized approximately the same as the pair of PFET passgates, each of the second pair of PFET passgates having a drain respectively coupled to the first and second cell notes of the first and second inverters;
second complementary bit lines, each of the second complementary bit lines respectively connected to a source of the second pair of PFET passgates; and
a second word line connected to a gate of each of the second pair of PFET passgates.
